(19) United States
(12) Patent Application Publication
(10) Pub. No.: US 2026/0237963 A1
(43) Pub. Date: Aug. 13, 2026

(54) OPTICAL DEVICE WITH RADIAL WIRE BONDS

(71) Applicant: Lumentum Operations LLC, San Jose, CA (US)

(72) Inventors: Charles TSAI, San Jose, CA (US); Siu Kwan CHEUNG, San Jose, CA (US); Graham BOUGH, San Jose, CA (US)

(21) Appl. No.: 19/095,899

(22) Filed: Mar. 31, 2025

Related U.S. Application Data
(60) Provisional application No. 63/755,662, filed on Feb. 7, 2025.

(51) Int. Cl. H01S 5/02345; H04B 10/50

(52) U.S. Cl. CPC H01S 5/02345; H04B 10/503

(57) ABSTRACT

In some implementations, an optical device includes a laser chip; a transmit optical subassembly (TOSA) chip; and a set of bond wires connecting the laser chip to an electrical trace on the TOSA chip, wherein the set of bond wires is arranged in a radial pattern.

### CROSS-REFERENCE TO RELATED APPLICATION

This Patent Application claims priority to U.S. Provisional Patent Application No. 63/755,662, filed on Feb. 7, 2025, and entitled “RADIAL WIRE BOND ARRANGEMENT.” The disclosure of the prior Application is considered part of and is incorporated by reference into this Patent Application.

### TECHNICAL FIELD

The present disclosure relates generally to optical devices and to optical devices with radial bond wires.

### BACKGROUND

High-power single-frequency semiconductor laser chips, such as for distributed feedback (DFB) lasers, are used in optical communication systems. Such laser chips may have a relatively stable wavelength and narrow linewidth. The laser chips may be integrated into transmitter optical sub-assemblies (TOSAs), which provide a compact and reliable packaging solution with precise optical alignment, thermal management, and electrical connectivity. TOSA-packaged DFB lasers are used in high-speed fiber optic networks, including dense wavelength division multiplexing (DWDM) and coherent communication systems, where high output power and spectral consistency are important parameters for long-distance data transmission.

### SUMMARY

In some implementations, an optical device includes a laser chip; a transmit optical subassembly (TOSA) chip; and a set of bond wires connecting the laser chip to an electrical trace on the TOSA chip, wherein the set of bond wires is arranged in a radial pattern.

In some implementations, an optical device includes a laser chip; a TOSA chip; and a set of bond wires connecting the laser chip to an electrical trace on the TOSA chip, wherein the set of bond wires is arranged in a radial pattern, wherein a first bond wire, of the set of bond wires, is associated with a first set of values for a set of characteristics and a second bond wire, of the set of bond wires, is associated with a second set of values for the set of characteristics.

In some implementations, an optical device includes a laser chip; a TOSA chip; and a set of bond wires connecting the laser chip to an electrical trace on the TOSA chip, wherein a first bond wire, of the set of bond wires, is disposed at an oblique angle to a second bond wire of the set of bond wires, wherein the oblique angle is associated with respective resistances of the first bond wire and the second bond wire.

### BRIEF DESCRIPTION OF THE DRAWINGS

FIG. 1 is a top-down view of an example optical device.

FIG. 2 is a side view of example optical devices with radial-patterned bonding wires.

FIG. 3 is an example of current density relative to longitudinal distance for wire bonding arrangements.

### DETAILED DESCRIPTION

The following detailed description of example implementations refers to the accompanying drawings. The same reference numbers in different drawings may identify the same or similar elements.

High-power single-frequency semiconductor laser chips can be incorporated into transmitter optical subassembly (TOSA) packaging, such as for distributed feedback (DFB) lasers. To connect a laser chip to a TOSA chip, a set of wirebonds may be provided which connect from a first set of electrodes on the laser chip to a second set of electrodes on the TOSA chip. Non-uniformity in current injection, either from edge injection or pogo-pin (e.g., spring-loaded pin) injection, occurring longitudinally along an active junction of the laser chip can induce new mode hops in laser output that disrupt the laser output. For example, the new mode hops can result in a desired single frequency output of the laser chip having disruptions, such as having multiple frequencies corresponding to the new mode hops. Occurrence of such disruptions may result in TOSA packages, which include the laser chips, being classified as defective and being scrapped. Accordingly, it is desirable to minimize mode hops by ensuring uniform current injection when a laser chip is connected to a TOSA chip in an optical device, such as a TOSA packaging.

Additionally, non-uniformity in current injection can cause discrepancies between performance observed when testing is performed on a chip-on-submount (COS) level relative to final performance testing performed on a TOSA level. The discrepancy may occur as a result of the locations of current injection being different when testing is performed on a COS level and when testing is performed on a TOSA level. Testing on the COS level is performed with pogo-pin probe points near a center of a submount and testing on the TOSA level is performed with edge injection near an edge of a TOSA. Accordingly, when bonding wires between a TOSA chip and a laser chip are arranged in a parallel arrangement, differences in current injection uniformity may result in testing discrepancies that can result in optical devices being rejected for failing to meet performance specifications.

Some implementations described herein provide a radial pattern for bonding wires associated with an optical device. For example, an optical device may include a laser chip mounted on a TOSA chip with a set of bonding wires, in a radial arrangement, electrically connecting the laser chip to the TOSA chip. Additionally, or alternatively, one or more other characteristics of the bonding wires may be configured to ensure that different bonding wires and associated electrical paths have a same electrical resistance, thereby balancing current injection and avoiding mode hops. In this way, the optical device may achieve uniformly distributed series resistance from a current source to an active laser region, resulting in kink-free performance. Based on achieving kink-free (e.g., discontinuity-free) performance and avoiding mode hops by assuring a net resistance along different electrical pathways remains uniform and there is a uniform current density in a laser gain region, a likelihood of an optical device being rejected for failing to meet performance standards is reduced. Furthermore, by avoiding mode hops, a performance level of an optical device may be improved, such as by improving a maintenance of a steady single wavelength by a laser chip of the optical device. Additionally, or alternatively, the arrangement of bonding wires, described herein, ensures a consistency of signal input and output assessment.

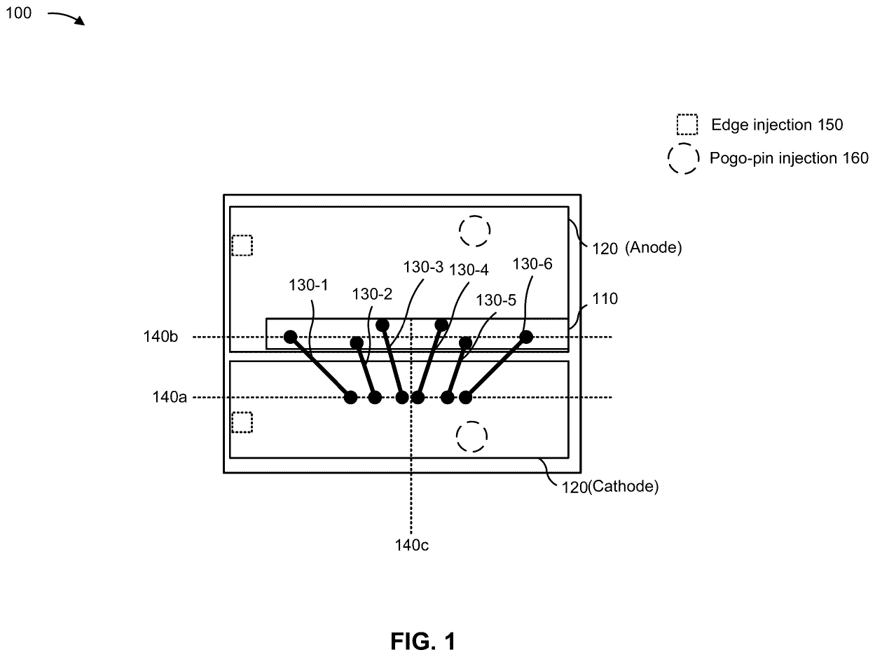

FIG. 1 is a top-down view of an example optical device 100. As shown in FIG. 1, the example optical device 100 may include a laser chip 110 and a TOSA chip 120.

In some implementations, the laser chip 110 may be electrically connected to the TOSA chip 120 (or to a submount for the TOSA chip 120 and the laser chip 110). For example, a set of bonding wires 130 may connect at a first set of ends to a first set of electrodes of the laser chip 110 and at a second set of ends to a second set of electrodes of the TOSA chip 120. In this way, the laser chip 110 is electrically connected to the TOSA chip 120 to enable the TOSA chip 120 to drive or control the laser chip 110, such as for an optical communications system, an optical measurement system (e.g., a gesture recognition system, light detection and ranging (LIDAR) system, or spectroscopy system), an optical manufacturing system (e.g., an optical cutting or welding system), optical medical system (e.g., a surgical laser system, a medical diagnosis system, or a dermatological treatment system), or another type of optical system. In some implementations, the set of bonding wires 130 may be attached to the laser chip 110 or the TOSA chip 120 using an automatic wire bonder.

In some implementations, the set of bonding wires 130 may be arranged in a radial pattern or “fan-like” pattern. For example, as shown in FIG. 1, a first bonding wire 130-1 may be disposed at an oblique angle to a second bond wire 130-2 or a third bond wire 130-3, among other examples. Accordingly, with respect to a horizontal orientation of the laser chip 110 and the TOSA chip 120, as shown, rather than each bonding wire being orthogonal to the laser chip 110 and the TOSA chip 120 (e.g., at a vertical orientation), at least one bonding wire 130 is at a non-orthogonal angle to the laser chip 110 and the TOSA chip 120. In some implementations, a subset of bonding wires 130 may be at orthogonal angles to the laser chip 110 and the TOSA chip 120 or may be parallel to each other. In other words, the radial pattern includes at least one bonding wire 130 at an oblique angle to at least one other bonding wire 130, but, in some implementations, may also include at least one bonding wire 130 parallel to at least one other bonding wire 130. Similarly, while the radial pattern includes at least one bonding wire 130 that is not disposed orthogonally to the laser chip 110 and the TOSA chip 120, in some implementations, there may be at least one other bonding wire 130 that is disposed orthogonally to the laser chip 110 and the TOSA chip 120.

In some implementations, bonding positions of the set of bonding wires 130 (e.g., on electrodes of the laser chip 110 and the TOSA chip 120) may be disposed with respect to a line. For example, as shown, on the TOSA chip 120, each bonding wire 130 may bond to the TOSA chip 120 uniformly along a line 140a. In contrast, in some implementations, on the laser chip 110, different bonding wires 130 may bond to the laser chip 110 non-uniformly with respect to line 140b (e.g., on on different sides (or along) a line 140b). For example, as shown, a first bonding wire 130-1 may bond on the line 140b, a second bonding wire 130-2 may bond below the line 140b, and a third bonding wire 130-3 may bond above the line 140b. Similarly, a fourth bonding wire 130-4 bonds above the line 140b, a fifth bonding wire 130-5 bonds below the line 140b, and a sixth bonding wire bonds along the line 140b.

In some implementations, the radial pattern with which the set of bonding wires 130 is arranged may have an axis of symmetry. For example, an axis of symmetry 140c may be disposed, such that bonding wires 130 on a left side of the axis of symmetry 140c are arranged at mirrored positions relative to the bonding wires 130 on a right side of the axis of symmetry 140c. In other words, bonding wire 130-1 may be mirror symmetric with bonding wire 130-6, bonding wire 130-2 may be mirror symmetric with bonding wire 130-5, and bonding wire 130-3 may be mirror symmetric with bonding wire 130-4. Additionally, or alternatively, the radial pattern may include an asymmetry with respect to one or more bonding wires 130. In other words, at least one bonding wire 130 may not have a mirror symmetric counterpart, in some implementations. In some implementations, an arrangement of placements of wire bond locations for the bonding wires 130 may be associated with a relationship p=L/(2w)+nL/w, where p is a position along line 140b, L is a cavity length of the laser chip 110, w is a quantity of bonding wires 130, and n is an integer value for each bonding wire 130 from 0 to w−1. Accordingly, as one example, for L=3 millimeters (mm), w=6, and n=0 to 5, bonding wires 130 may be disposed at positions of p={0.25 mm, 0.75 mm, 1.25 mm, 1.75 mm, 2.25 mm, and 2.75 mm}.

In some implementations, a separation between bonding positions of the set of bonding wires 130 may differ for different pairs of adjacent ends of bonding wires. For example, a horizontal separation between bonding wires 130-1 and 130-2 may be a first amount of separation that is larger than a second amount of separation between bonding wires 130-2 and 130-3. In some implementations, a first set of ends of the bonding wires 130 bonded to the laser chip 110 may have a first separation and a second set of ends of the bonding wires 130 bonded to the laser chip 110 may have a second separation. In this case, the relative amount of separation between ends of the bonding wires 130 may be based on a corresponding electrical resistance of the chip to which the ends are bonded. In other words, a magnitude of the first separation relative to a magnitude of the second separation is associated with a first electrical resistance of a first electrical trace of the laser chip 110 relative to a second electrical resistance of a second electrical trace of the TOSA chip 120. A trace resistance between adjacent ends of bonding wires 130 is an electrical resistance value along an electrical trace between locations of the two ends. Accordingly, a trace resistance between a first pair of adjacent ends at a first side of the bonding wires 130 may correspond to a trace resistance between corresponding adjacent ends in the second set of ends. Accordingly, a length or angle of the bonding wires 130 may be associated with balancing the trace resistances, such that the length or angle of the bonding wires 130 is based on or corresponds to a difference in respective resistances of the laser chip 110 and the TOSA chip 120. In some implementations, the set of bonding wires 130 may include a particular quantity of bonding wires. For example, the set of bonding wires 130 may include 6 or more bonding wires (e.g., 6, 7, 8, 9, 10, or another quantity of bonding wires). Higher quantities of radial bonding wires may be used for higher current and higher power applications.

In some implementations, the bonding wires 130 may each be associated with a set of characteristics for which different bonding wires 130 have different values. For example, a first bonding wire 130-1 may have a first set of values for the set of characteristics and a second bonding wire 130-2 may have a second set of values for the set of characteristics. The set of characteristics may include characteristics, such as a wirebond length, a wirebond diameter, a wirebond loop height, a material type, or a presence of a resistive element. For example, the bonding wire 130-1 may have a first length (e.g., a length of the bonding wire, in three dimensions, from laser chip 110 to TOSA chip 120), but a bonding wire 130-2 may have a second length. Similarly, the first bonding wire 130-1 may have a first diameter or cross-sectional area, but the bonding wire 130-2 may have a second diameter or cross-sectional area.

Similarly, and as described below, with respect to a vertical dimension, the first bonding wire 130-1 may extend to a first height (or have a first vertical profile) above the laser chip 110 and the TOSA chip 120, but the second bonding wire 130-2 may extend to a second height (or have a second vertical profile) above the laser chip 110. Additionally, or alternatively, the first bonding wire 130-1 may be manufactured from a first material (e.g., with a first conductivity) and the second bonding wire 130-2 may be manufactured from a second material (e.g., with a second conductivity). Additionally, or alternatively, resistive elements, such as resistive chokes, may be patterned onto planar electrodes to which the bonding wires 130 are bonded. Accordingly, the first bonding wire 130-1 may be in proximity to a resistive element with a first resistance, but the second bonding wire 130-2 may not be in proximity to any resistive element (or may be in proximity to a resistive element with a second resistance).

Although some implementations are described herein in terms of different bonding wires 130 having different values for one or more characteristics, it is contemplated that some bonding wires 130 may have the same values for one or more characteristics. For example, first bonding wire 130-1 and sixth bonding wire 130-6 may have the same wirebond length, but the first bonding wire 130-1 and the second bonding wire 130-2 may have different wirebond lengths. Similarly, in some implementations, all the bonding wires 130 may be manufactured from the same material.

In some implementations, a set of characteristics of the set of bonding wires 130 or the radial pattern thereof is configured in connection with a pathway resistance of the set of bonding wires 130. For example, an angular orientation of the bonding wire 130-1 relative to an angular orientation of the bonding wire 130-2 is configured to ensure that respective pathway resistances of the bonding wire 130-1 and the bonding wire 130-2 are within a threshold amount of each other, such as within 20%, within 10%, or within 5%, among other examples. By maintaining pathway resistances of each bonding wire 130 within the threshold percentage of each other bonding wire 130, the optical device 100 reduces a likelihood of mode hops, which can result in the optical device 100 being classified as defective. Because mode hops occur when a threshold differential is reached, reducing the differences in respective pathway resistances to less than a threshold amount can eliminate mode hops even when some, non-zero level of pathway resistance differential remains.

Additionally, or alternatively, other characteristics may be selected or optimized in connection with balancing pathway resistances between different bonding wires 130. For example, wirebond lengths, wirebond diameters, wirebond loop heights, material types, or the patterning of resistive elements may be configurable parameters to ensure that pathway resistances of each bonding wire 130 is within a threshold percentage of each other bonding wire 130. In other words, angles of the radial pattern may be selected to cause each bonding wire 130 to have a particular wirebond length, which, in connection with selected wirebond diameters, wirebond loop heights, material types, or resistive elements, may result in a net resistance along each pathway of each bonding wire 130 being the same value (or within a threshold percentage of the same value). In this way, the optical device can achieve a uniform current density, such as a current density, across a laser gain region of the laser chip 110, within approximately 10%, 5%, 2%, or 1% of a mean value, thereby suppressing mode hopping by the laser chip 110.

As shown by reference numbers 150 and 160, current injection may be performed for testing of the optical device 100. For example, current injection may occur using pogo-pin probe points, as shown by reference number 160, or by using edge injection (e.g., via wire bonds), as shown by reference number 150. As described above, by configuring the bonding wires 130 to achieve a uniform current density, the optical device 100 may have a reduced discrepancy (or no discrepancy) between testing performed using pogo-pin injection at a COS level and testing performed using edge injection at a TOSA level. Moreover, based on balancing the respective pathway resistances of different bonding wires 130, the radial arrangement of bonding wires 130 may obviate a need to manufacture different electrical pathways for different types of testing (e.g., pogo-pin injection testing versus edge injection testing).

As indicated above, FIG. 1 is provided as an example. Other examples may differ from what is described with regard to FIG. 1.

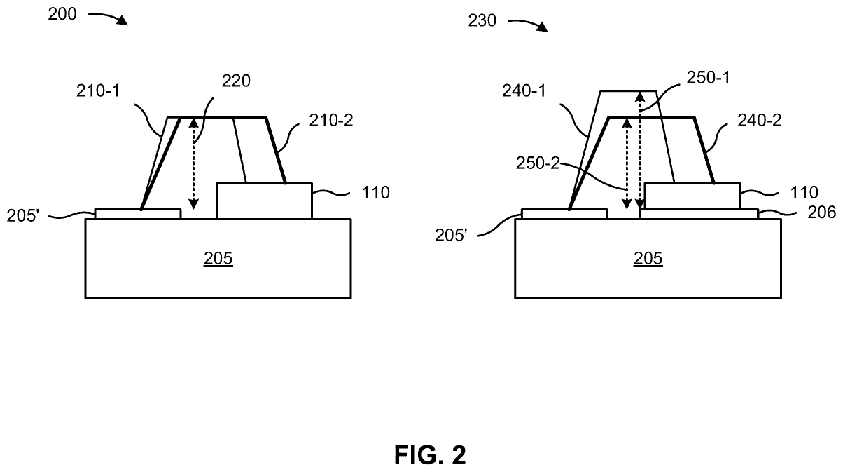

FIG. 2 is a side view of example optical devices with radial-patterned bonding wires. For example, as shown in FIG. 2, a first optical device 200 may include a laser chip 110 bonded onto an anode 206 of a substrate 205. The substrate 205 may include a trace 205′ (e.g., a cathode). In some implementations, the substrate 205 may be a substrate of a TOSA chip 120. Although the trace 205′ is shown on top of the substrate 205 it is contemplated that the trace 205′ may be embedded in the substrate 205 and may have a surface that is approximately co-planar with a top of the substrate 205. In this case, to electrically connect respective electrodes of the laser chip 110 and the trace 205′, a set of bonding wires (in a radial pattern) is provided. As shown, in the side view, a first bonding wire 210-1 may have a first vertical profile and a second bonding wire 210-2 may have a second vertical profile. In other words, although both bonding wires 210 reach the same wirebond loop height 220 above a surface of the trace 205′, the bonding wires 210 rise from the same point on the trace 205′ but descent to different points on the laser chip 110, resulting in different vertical profiles, as shown. Similarly, a second optical device 230, with the laser chip 110 disposed on the TOSA chip 120, may include a set of bonding wires with different vertical profiles and different wirebond loop heights. For example, a first bonding wire 240-1 may rise to a wirebond loop height 250-1, whereas a second bonding wire 240-2 may rise to a second wirebond loop height 250-2. As described above, a wirebond loop height (or vertical profile) or wirebond length of a bonding wire may be selected to balance resistances of respective electrical paths of the different bonding wires.

As indicated above, FIG. 2 is provided as an example. Other examples may differ from what is described with regard to FIG. 2.

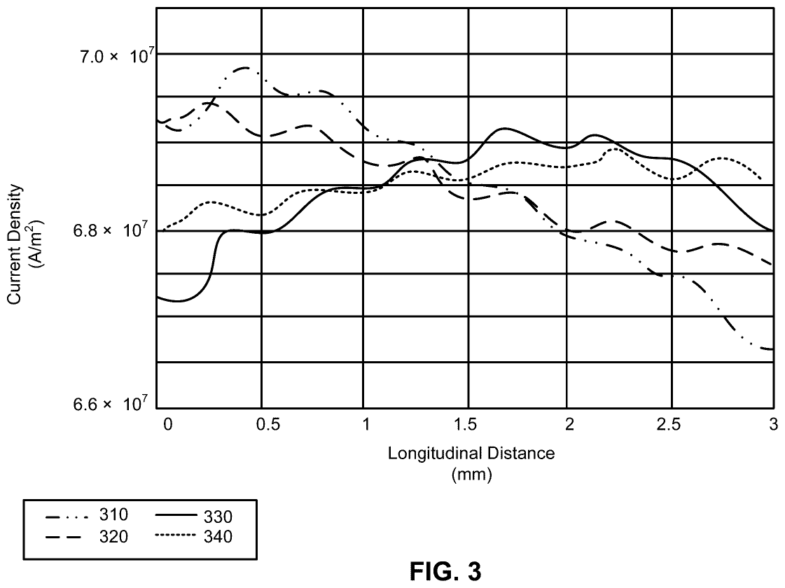

FIG. 3 is an example of current density relative to longitudinal distance for wire bonding arrangements.

As shown in FIG. 3, the current density relative to longitudinal distance in an active region is determined for edge injection with a parallel arrangement of wire bondings (reference number 310), edge injection with a radial arrangement of wire bondings (reference number 320), pogo-pin injection with a parallel arrangement of wire bondings (reference number 330), and pogo-pin injection with a radial arrangement of wire bondings (reference number 340). Here, a differential between results from pogo-pin injection relative to edge injection is reduced by over 40% when using a radial arrangement (reference numbers 320 and 340) relative to when using a parallel arrangement (reference numbers 310 and 330).

As indicated above, FIG. 3 is provided as an example. Other examples may differ from what is described with regard to FIG. 3.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

As used herein, satisfying a threshold may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”). Further, spatially relative terms, such as “below,” “lower,” “above,” “upper,” and the like, may be used herein for ease of description to describe one element or feature's relationship to another element(s) or feature(s) as illustrated in the figures. The spatially relative terms are intended to encompass different orientations of the apparatus, device, and/or element in use or operation in addition to the orientation depicted in the figures. The apparatus may be otherwise oriented (rotated 90 degrees or at other orientations) and the spatially relative descriptors used herein may likewise be interpreted accordingly.

What is claimed is:

1. An optical device, comprising:
a laser chip;
a transmit optical subassembly (TOSA) chip; and
a set of bond wires connecting the laser chip to an electrical trace on the TOSA chip,
wherein the set of bond wires is arranged in a radial pattern.

2. The optical device of claim 1, wherein the set of bond wires includes a first set of ends attached to the laser chip and a second set of ends attached to the TOSA chip.

3. The optical device of claim 2, wherein a first pair of adjacent ends of the first set of ends is associated with a first amount of separation and a second pair of adjacent ends of the second set of ends is associated with a second amount of separation, and wherein the first amount of separation is larger than the second amount of separation.

4. The optical device of claim 2, wherein a difference in lengths of the set of bond wires is associated with a difference in electrical resistances of the TOSA chip and the laser chip.

5. The optical device of claim 1, wherein the radial pattern is configured such that respective pathway resistances of the set of bond wires are all within a threshold amount of each other.

6. The optical device of claim 5, wherein a first set of ends, of the set of bond wires, disposed on the laser chip is arranged uniformly along a first line, and wherein a second set of ends, of the set of bond wires, disposed on the TOSA chip is arranged non-uniformly along a second line.

7. The optical device of claim 6, wherein each end, of the first set of ends, is disposed along the first line.

8. The optical device of claim 6, wherein a first end, of the second set of ends, is disposed on a first side of the second line and a second end, of the second set of ends, is disposed on a second side of the second line.

9. An optical device, comprising:
a laser chip;
a transmit optical subassembly (TOSA) chip; and
a set of bond wires connecting the laser chip to an electrical trace on the TOSA chip,
wherein the set of bond wires is arranged in a radial pattern,
wherein a first bond wire, of the set of bond wires, is associated with a first set of values for a set of characteristics and a second bond wire, of the set of bond wires, is associated with a second set of values for the set of characteristics.

10. The optical device of claim 9, wherein the set of characteristics includes at least one of:
a wirebond length,
a wirebond diameter,
a wirebond loop height,
a material type, or
a presence of a resistive element.

11. The optical device of claim 10, wherein the resistive element is patterned into a planar electrode of the optical device.

12. The optical device of claim 9, wherein a net resistance along a plurality of pathways associated with the set of bond wires is a same value.

13. The optical device of claim 9, wherein the first set of values and the second set of values for the set of characteristics are selected to suppress mode hopping by the laser chip.

14. The optical device of claim 9, wherein a current density, across a laser gain region of the laser chip, is within approximately 5% of a mean value.

15. The optical device of claim 9, wherein a quantity of bond wires, in the set of bond wires, is 6 or more bond wires.

16. An optical device, comprising:
a laser chip;
a transmit optical subassembly (TOSA) chip; and
a set of bond wires connecting the laser chip to an electrical trace on the TOSA chip,
wherein a first bond wire, of the set of bond wires, is disposed at an oblique angle to a second bond wire of the set of bond wires,
wherein the oblique angle is associated with respective resistances of the first bond wire and the second bond wire.

17. The optical device of claim 16, wherein the oblique angle forms a radial pattern.

18. The optical device of claim 16, wherein a third bond wire, of the set of bond wires, is disposed parallel to the first bond wire or the second bond wire.

19. The optical device of claim 16, wherein the oblique angle is configured such that respective pathway resistances of the first bond wire and the second bond wire are within a threshold amount of each other.

20. The optical device of claim 16, wherein the first bond wire and the second bond wire have a same length.
